(19) United States
(12) Patent Application Publication
(10) Pub. No.: US 2019/0324859 A1
(43) Pub. Date: Oct. 24, 2019

(54) Method and Apparatus for Restoring Data after Power Failure for An Open-Channel Solid State Drive

(71) Applicant: CNEX Labs, Inc., San Jose, CA (US)

(72) Inventors: Alan Armstrong, Los Gatos, CA (US); Javier González González, Copenhagen (DK); Yiren Ronnie Huang, San Jose, CA (US)

(73) Assignee: CNEX Labs, Inc., San Jose, CA (US)

(21) Appl. No.: 16/389,949

(22) Filed: Apr. 20, 2019

Related U.S. Application Data
(60) Provisional application No. 62/660,561, filed on Apr. 20, 2018.

(51) Int. Cl. G06F 11/14; G06F 12/02; G11C 29/52; G06F 13/16; G11C 16/30

(52) U.S. Cl. CPC G06F 11/1441; G06F 12/0246; G11C 16/30; G06F 13/1673; G11C 29/52

(57) ABSTRACT

The power protection system includes a host driver in the host system and an SSD driver situated in an SSD. In one aspect, the host driver includes a write buffer able to store information during a write operation to an open-channel solid state drive (“OCSSD”). The SSD driver connected to the host driver via a bus includes an SSD double data rate (“DDR”) buffer configured to store a copy of content similar to content in the write buffer and an SSD nonvolatile memory (“NVM”) coupled to the SSD DDR buffer and configured to preserve the data stored in the SSD DDR buffer when a power failure is detected. The SSD driver also includes a power supply, which can be a capacitor, coupled to the SSD DDR buffer for providing power to the SSD DDR buffer when the power is lost.

### PRIORITY

This application claims the benefit of priority based upon U.S. Provisional Patent Application Ser. No. 62/660,561, filed on Apr. 20, 2018 in the name of the same inventor and entitled “Method and Apparatus for Restoring Data after Power Failure for An Open-Channel Solid State Drive,” the disclosure of which is hereby incorporated into the present application by reference.

### FIELD

The exemplary embodiment(s) of the present invention relates to the field of semiconductor and integrated circuits. More specifically, the exemplary embodiment(s) of the present invention relates to non-volatile memory (“NVM”) storage devices.

### BACKGROUND

With increasing popularity of electronic devices, such as computers, smart phones, mobile devices, server farms, mainframe computers, and the like, the demand for more and faster data is constantly growing. To handle and facilitate voluminous data between such electronic devices, high speed NV memory devices are typically required. A conventional type of NV memory device, for example, is a flash-based storage device such as solid-state drive (“SSD”).

The flash-based SSD, for example, is an electronic NV computer storage device capable of maintaining, erasing, and/or reprogramming data. The flash memory can be fabricated with several different types of integrated circuit (“IC”) technologies such as NOR or NAND logic gates with, for example, floating-gate transistors. Depending on the applications, a typical memory access of flash memory is organized as a block, a page, a word, and/or a byte.

A class of SSDs is Open-Channel SSDs (“OCSSDs”) which are typically different from the traditional SSDs. The OCSSD, for example, allows the host to control and maintain various features, such as I/O isolation, predictable latencies, and software-defined non-volatile memory management. I/O isolation, for example, divides the storage space of an SSD into multiple blocks or logical units for mapping to the parallel units of the SSD. The predictable latency allows the host to manage and/or decide when or where the I/O commands should be sent. The NV management permits the host to manage storage location and/or scheduling access applications.

A problem associated with a conventional OCSSD is that it typically takes a long time to restore the data in the buffer after an unintended power loss.

### SUMMARY

The power protection system includes a host driver in the host system and an SSD driver situated in an SSD. In one aspect, the host driver includes a write buffer able to store information during a write operation to an open-channel solid state drive (“OCSSD”). The SSD driver connected to the host driver via a bus includes an SSD double data rate (“DDR”) buffer configured to store a copy of content similar to content in the write buffer and an SSD nonvolatile memory (“NVM”) coupled to the SSD DDR buffer and configured to preserve the data stored in the SSD DDR buffer when a power failure is detected. The SSD driver also includes a power supply, which can be a capacitor, coupled to the SSD DDR buffer for providing power to the SSD DDR buffer when the power is lost.

In one aspect, upon detecting a power failure at the host system, the data in the SSD local memory is maintained for a predefined period time by a capacitor(s) after power failed. The data in the SSD local memory is transferred to a predefined NVM block for saving the data persistently while the data in the SSD local memory is maintained by the capacitor. After detecting restoration of power at the host system, the data is restored from the predefined NVM block to the SSD local memory. The process subsequently loads the data including metadata from the SSD local memory to the buffer in the host system allowing the host system and the OCSSD to resume the memory access at the location or step immediately before the power failure.

Additional features and benefits of the exemplary embodiment(s) of the present invention will become apparent from the detailed description, figures and claims set forth below.

### BRIEF DESCRIPTION OF THE DRAWINGS

The exemplary embodiment(s) of the present invention will be understood more fully from the detailed description given below and from the accompanying drawings of various embodiments of the invention, which, however, should not be taken to limit the invention to the specific embodiments, but are for explanation and understanding only.

FIGS. 1A-1B are block diagrams illustrating a scheme of data restoration in host via a non-volatile memory (“NVM”) backup device in an OCSSD storage environment in accordance with one embodiment of the present invention;

FIG. 2 is a block diagram illustrating a mechanism of power loss protection using backup power supply and NVM in accordance with one embodiment of the present invention;

FIG. 3 is a block diagram illustrating data restoration due to power failure in accordance with one embodiment of the present invention;

FIG. 4 is a block diagram illustrating a non-volatile memory (“NVM”) device operating as OCSSD in accordance with one embodiment of the present invention;

FIGS. 5-6 are flowcharts illustrating a process of data protection upon detection of an unintended power loss in an OCSSD storage environment in accordance with one embodiment of the present invention;

FIG. 7 is a diagram illustrating a computer network capable of providing data storage using power failure protected OCSSD in accordance with one embodiment of the present invention; and

FIG. 8 is a block diagram illustrating a digital processing system capable of operating power failure protected OCSSD in accordance with one embodiment of the present invention.

### DETAILED DESCRIPTION

Embodiments of the present invention are described herein with context of a method and/or apparatus for data restoration relating to an open-channel solid-state drive (“OCSSD”).

The purpose of the following detailed description is to provide an understanding of one or more embodiments of the present invention. Those of ordinary skills in the art will realize that the following detailed description is illustrative only and is not intended to be in any way limiting. Other embodiments will readily suggest themselves to such skilled persons having the benefit of this disclosure and/or description.

In the interest of clarity, not all of the routine features of the implementations described herein are shown and described. It will, of course, be understood that in the development of any such actual implementation, numerous implementation-specific decisions may be made in order to achieve the developer's specific goals, such as compliance with application- and business-related constraints, and that these specific goals will vary from one implementation to another and from one developer to another. Moreover, it will be understood that such a development effort might be complex and time-consuming, but would nevertheless be a routine undertaking of engineering for those of ordinary skills in the art having the benefit of embodiment(s) of this disclosure.

Various embodiments of the present invention illustrated in the drawings may not be drawn to scale. Rather, the dimensions of the various features may be expanded or reduced for clarity. In addition, some of the drawings may be simplified for clarity. Thus, the drawings may not depict all of the components of a given apparatus (e.g., device) or method. The same reference indicators will be used throughout the drawings and the following detailed description to refer to the same or like parts.

In accordance with the embodiment(s) of present invention, the components, process steps, and/or data structures described herein may be implemented using various types of operating systems, computing platforms, computer programs, and/or general-purpose machines. In addition, those of ordinary skills in the art will recognize that devices of a less general-purpose nature, such as hardware devices, field programmable gate arrays (FPGAs), application specific integrated circuits (ASICs), or the like, may also be used without departing from the scope and spirit of the inventive concepts disclosed herein. Where a method comprising a series of process steps is implemented by a computer or a machine and those process steps can be stored as a series of instructions readable by the machine, they may be stored on a tangible medium such as a computer memory device (e.g., ROM (Read Only Memory), PROM (Programmable Read Only Memory), EEPROM (Electrically Erasable Programmable Read Only Memory), FLASH Memory, Jump Drive, and the like), magnetic storage medium (e.g., tape, magnetic disk drive, and the like), optical storage medium (e.g., CD-ROM, DVD-ROM, paper card and paper tape, and the like) and other known types of program memory.

The term “system” or “device” is used generically herein to describe any number of components, elements, sub-systems, devices, packet switch elements, packet switches, access switches, routers, networks, computer and/or communication devices or mechanisms, or combinations of components thereof. The term “computer” includes a processor, memory, and buses capable of executing instruction wherein the computer refers to one or a cluster of computers, personal computers, workstations, mainframes, or combinations of computers thereof.

The power protection system includes a host driver in the host system and an SSD driver situated in an SSD. In one aspect, the host driver includes a write buffer able to store information during a write operation to an open-channel solid state drive (“OCSSD”). The SSD driver connected to the host driver via a bus includes an SSD double data rate (“DDR”) buffer configured to store a copy of content similar to content in the write buffer and an SSD nonvolatile memory (“NVM”) coupled to the SSD DDR buffer and configured to preserve the data stored in the SSD DDR buffer when a power failure is detected. The SSD driver also includes a power supply, which can be a capacitor, coupled to the SSD DDR buffer for providing power to the SSD DDR buffer when the power is lost.

Note that an OCSSD is a solid-state drive. The OCSSD does not have a firmware Flash Translation Layer (“FTL”) implemented on the device, but instead leaves the management of the physical solid-state storage to the computer's operating system

One embodiment of the method and/or apparatus is directed to restore data due to a power failure during memory access to an open-channel solid state drive (“OCSSD”). The process, in one embodiment, monitors and receives a command such as a write command from a host system for accessing one or more non-volatile memory (“NVM”) pages. After loading data from a buffer in a host system to an SSD local memory via a bus connecting the host system and the OCSSD, a backup acknowledge signal is sent from the OCSSD to the host system when the data in the buffer is coped to the SSD local memory. The process subsequently issues an input and output (“IO”) commend acknowledge signal by the host system in response to the backup acknowledge signal.

In one aspect, upon detecting a power failure at the host system, the data in the SSD local memory is maintained for a predefined period time by a capacitor. The data in the SSD local memory is transferred to a predefined NVM block for saving the data persistently while the data in the SSD local memory is maintained by the capacitor. After detecting a restoration of power at the host system, the data is restored from the predefined NVM block to the SSD local memory. The process subsequently loads the data including metadata from the SSD local memory to the buffer in the host system allowing the host system and the OCSSD to resume the memory access at the location or step immediately before the power failure.

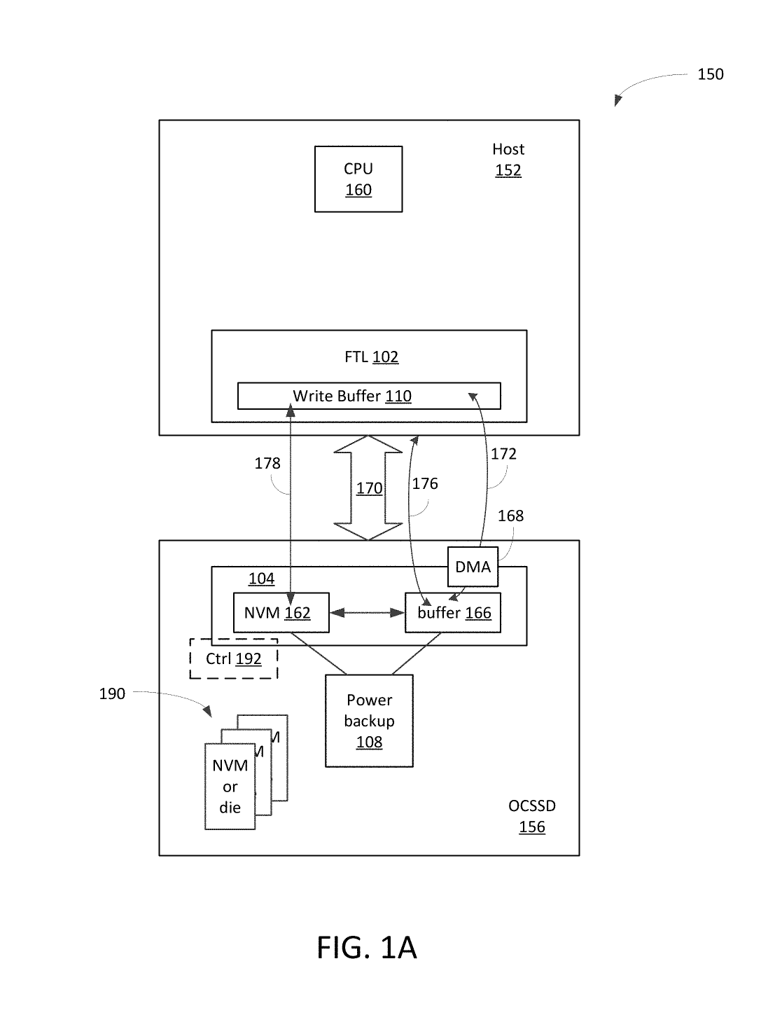

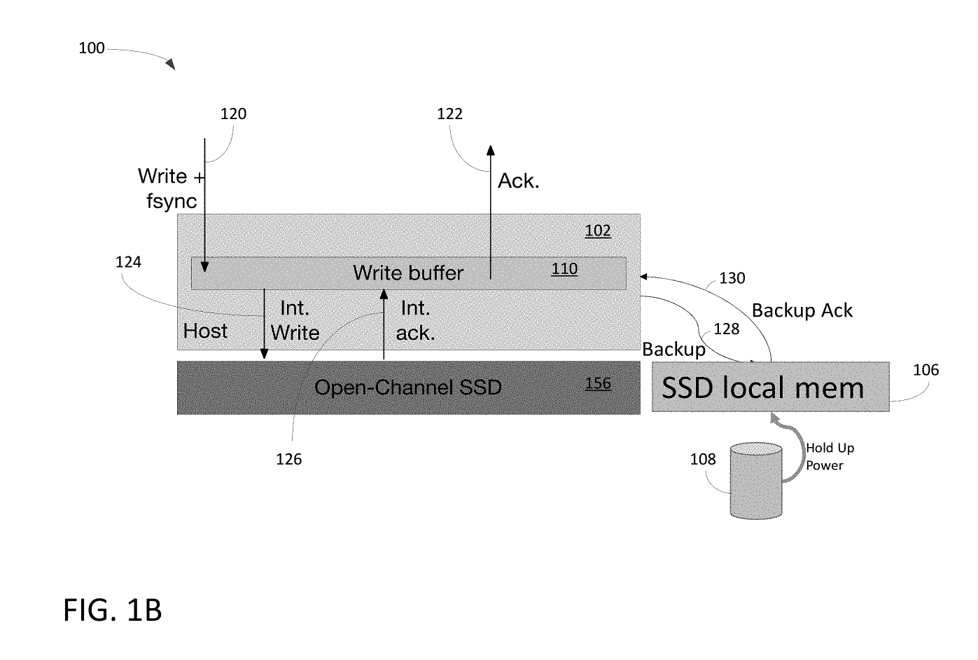

FIG. 1A is a block diagram 150 illustrating a scheme of data restoration in host via an NVM backup device in an OCSSD storage environment in accordance with one embodiment of the present invention. Diagram 150 includes a host or host system 152, OCSSD or SSD 156, and bus 170. To implement OCSSD, host 152 includes a central processing unit (“CPU”) 160 and a flash translation layer (“FTL”) driver 102 which is used to facilitate memory access in the OCSSD. In one aspect, FTL driver 102 further includes a write buffer 110. It should be noted that the underlying concept of the exemplary embodiment(s) of the present invention would not change if one or more blocks (or devices) were added to or removed from diagram 150.

Bus 170 is used to couple Host 152 to OCSSD 156 for facilitating signal transmission. In one aspect, bus 170 is able to provide data communication for facilitating implementation of logic buses or connections 172-178. Bus 170 can be implemented by various bus protocols, such as, but not limited to, NVM Express (NVMe), PCI Express (PCIe), SATA Express, Serial ATA (SATA), Serial attached SCSI (SAS), Universal Serial Bus (USB), and the like.

Host 152 is a digital processing system capable of executing instructions. Host 152 can be referred to as a host system, computer system, computer, portable device, smart phone, server, router, switches, cloud storage and computing, autonomous vehicles, artificial intelligence system, and the like. To simplify the forgoing discussion, the term “host” is used to referred to any types of digital processing systems. Host 152, in one aspect, includes CPU 160, FTL or FTL driver 102, and a write buffer 110. In one embodiment, write buffer 110 is a part of FTL 102. FTL 102 is used to facilitate storage or memory access to and from one or more OCSSDs.

OCSSD or SSD 156, which is a solid-state NV memory storage, includes a driver or SSD driver 104, direct memory access (“DMA”) 168, memory controller 192, backup power 108, and NVMs 190. In one embodiment, SSD driver 104 further includes a buffer restoration NVM and a buffer 166. Buffer 166 which is a volatile memory can be a double data rate (“DDR”) buffer or memory configured to provide fast memory access. NVMs 190, which can be divided into LUN (logic unit number), block, and/or pages, are used to store data persistently. To simplify forgoing discussion, the terms “OCSSD” and “SSD” mean similar devices and can be used interchangeably.

OCSSD 156, in one embodiment, includes a power protection system (“PPS”) which can be implemented in SSD driver 104, controller 192, FTL 102, and/or a combination of SSD driver 104, FTL 102, and controller 192 with power backup unit 108. In one aspect, the PPS is configured to protect data loss in the middle of a write operation due to a power failure. The PPS includes a host driver or FTL 102 and SSD driver 104 wherein the host driver which is situated in the host is configured to have write buffer 110 capable of storing information during a write operation.

SSD driver 104, in one embodiment, is resided or situated in SSD or OCSSD 156 and capable of communicating with FTL 102 or host driver via an external bus such as bus 170. SSD driver 104 includes an SSD DDR buffer 166, SSD NVM 162, and power supply or backup power supply 108. SSD DDR buffer 166 is used to store a copy of content similar to the content in write buffer 110. SSD NVM 162, also known as buffer restoring NVM, is capable of preserving the data stored in the SSD DDR buffer when a power failure is detected. Backup power supply 108 coupled to SSD DDR buffer 166 provides power to buffer 166 when the power powering the system is lost. In one example, backup power supply 108 is a capacitor.

The PPS, in one embodiment, maintains a copy of the content in buffer 166 that is similar or the same to the content in write buffer 110 using the function of DMA 168 via a logic connection 172. In one example, the content in buffer 166 can also be used by a read function via a logic connection 176. Upon detecting a power failure, the content in buffer 166 is transferred to NVM 162 for data preservation with the backup power supplied by backup power 108. Once the power is restored, the content saved in NVM 162 is populated to buffer 166 as well as write buffer 110 via connections or buses 176-178. Depending on the applications, write buffer 110 can either be restored or reloaded the content from buffer 166 via connection 176 or from NVM 162 via connection 178.

It should be noted that a benefit of using OCSSD to allow the host such as host 152 to manage minimum write size, optical write size, and/or number of sectors that must be written before a read. For example, a host-side buffer includes mw_cuints which is set to the number of sectors to be cached per parallel unit (LUN). To implement OCSSD, memory writes are synchronous to allow host I/O scheduling (LUN busy map) and are aligned with applications and filesystem to reuse the buffers. For example, the support for zoned devices such as singled magnetic recording (SMR) makes the transition easier (e.g., F2FS (flash friendly file system) supports). Also, the buffer is managed by the application or file system so that the power fail (“pfail”) scheme may be directly implemented into its data structures. It should be noted that OCSS also provides a flexible architecture allowing cooperation between host and device as opposed to traditional redundancy.

The benefit(s) of using OCSSD includes improved cost by eliminating DRAM space for the write buffer as well as faster validation in which the FW (firmware) requires less changes across NAND generations. Note that the host buffer could be 24 MB. It should be noted that, according to OCSSD, a write is acknowledged when it reaches the host-side buffer and file synchronization (“Fsync”) requires that the host-side write buffer is flushed before the write is acknowledged. The write buffer flush means copying the content of write buffer such as buffer 110 to OCSSD buffer such as buffer 166.

An advantage of using the PPS in an OCSSD storage environment is that it provides fast data restoration in the host side of writing buffer whereby the applications of OCSSD can reap the benefit of flexibility, mapping table consolidation, and efficient I/O scheduling without concerning unintended power shortage.

FIG. 1B is a block diagram 100 illustrating a scheme of data restoration in a host buffer via an NVM backup device in an OCSSD storage environment in accordance with one embodiment of the present invention. Diagram 100 includes FTL driver 102, OCSSD 156, and SSD local memory 106 wherein SSD local memory 106, in one embodiment, is a part of OCSSD 156. SSD local memory 106 is coupled to a backup power 108 used for holdup power for a predefined period of time when a power failure is detected. It should be noted that the underlying concept of the exemplary embodiment(s) of the present invention would not change if one or more blocks (or devices) were added to or removed from diagram 100.

In operation, when the host issues a write fsync 120, FTL 102 writes the content to OCSSD 156 as indicated by numeral 124. Upon receipt of the interface (int.) write 124, OCSSD 156 issues an interface (int.) acknowledgement 126 to FTL 102 indicating the content is in SSD or SSD local memory 106 which is backup by a backup power supply such as a capacitor. After receipt of int. acknowledgement 126, FTL 102 issues an acknowledgement 122 to the host. Upon detecting a power failure, FTL 102 issues a backup command as indicated by numeral 128. After saving the content in an NVM, OCSSD sends a backup acknowledgement (“ack”) back to FTL 102 as indicated by numeral 120.

Diagram 100 illustrating power loss protection using one or more capacitors and NVM for Pfail save and power up restoration. For example, when a write or write+fsync is received, data is first copied to host write buffer and subsequently the data is backup in SSD local memory. After the backup in SSD local memory acknowledged, the IO write command ack is sent to the application. When Pfail happen, the FW (firmware) or the PPS saves the content in the SSD local memory backup region to the OCSSD SLC (single layer cell) block using a big capacitor to hold up the power for sufficient time for the data to be saved in the NVM. When the power is up at a later time, FW restores the data in the SSD backup region. Host driver can then load the backup contents back to the host side write buffer and continue the IO operation.

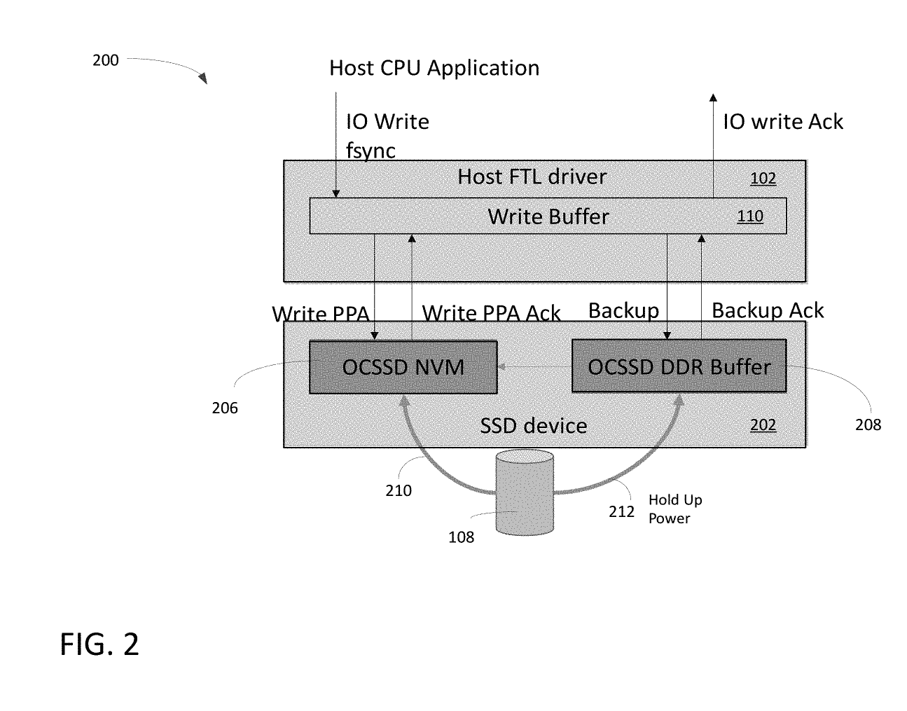

FIG. 2 is a block diagram 200 illustrating a mechanism of power loss protection using backup power supply and NVM in accordance with one embodiment of the present invention. Diagram 200 includes FTL driver 102, SSD driver 202 in the SSD wherein SSD driver 202 includes an OCSSD NVM 206, OCSSD DDR buffer 208, and backup power 108. Backup power, which can be a capacitor, is coupled to OCSSD NVM 206 and OCSSD DDR buffer 208 via connections 210-212. In one embodiment, OCSSD NVM 206 is capable of performing similar functions as NVM 162 shown in FIG. 1A. Also, OCSSD DDR buffer 208 is able to perform similar functions as buffer 166 shown in FIG. 1A. It should be noted that the underlying concept of the exemplary embodiment(s) of the present invention would not change if one or more blocks (or elements) were added to or removed from diagram 200.

In one embodiment, host FTL driver or FTL 102 has a write procedure with power fail protection. When a host CPU application issues an IO write to host FTL driver 102, FTL driver 102 applies data copying from the application memory to the host side write buffer and issues a backup command to save the data and/or meta data to the SSD so that data and meta data is saved in the SSD DRAM buffer. SSD DRAM buffer 208 is protected by the SSD capacitor (big CAP or super CAP) for an unintended power loss. When the backup command is acknowledged, host FTL driver 102 returns an IO write Acknowledge to host application. When the host side write buffer such as write buffer 208 has enough data to be written to the OCSSD NV memory such as NVM 206, FTL driver 102 issues a write to PPA (Physical Page Address) to the OCSSD NV memory. After the write PPA command is acknowledged, the host side write buffer is then released.

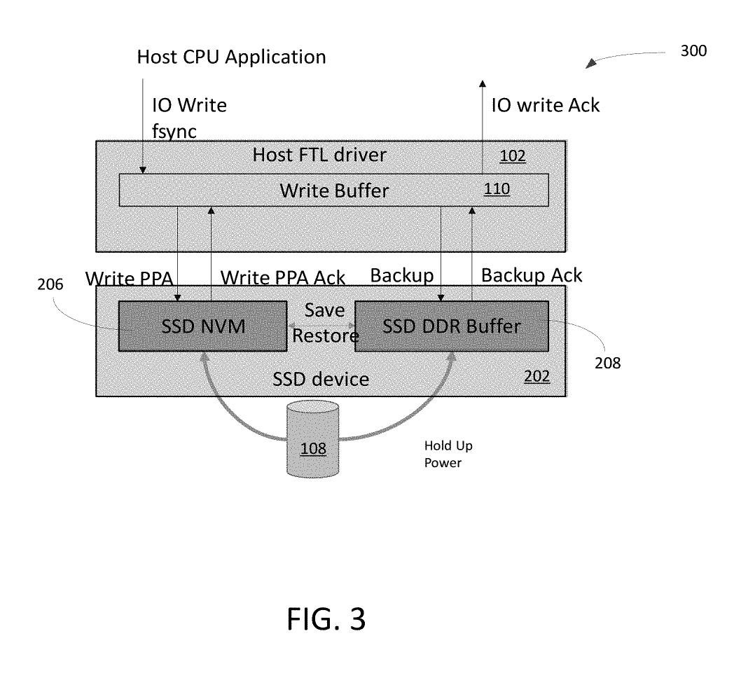

FIG. 3 is a block diagram 300 illustrating data restoration due to a power failure in accordance with one embodiment of the present invention. Diagram 300 is similar to diagram 200 shown in FIG. 2 with additional details about power failure protection. Diagram 300 includes FTL driver 102, SSD driver 202 in the SSD wherein SSD driver 202 includes an SSD NVM 206, SSD DDR buffer 208, and backup power 108. It should be noted that the underlying concept of the exemplary embodiment(s) of the present invention would not change if one or more blocks (or elements) were added to or removed from diagram 300.

In operation, when the FW or PPS receives power fail interrupt, FW saves the content of the DDR buffer area that is reserved for the host write backup buffer. After saving both data and meta data as a result, the FW saves the data and meta data to the SLC area of the NV memory for faster write speed and reliability. It should be noted that a capacitor (“CAP”) or big CAP/Super CAP on SSD may be used to hold the power while the FW is saving the data. At the power-up or power restoration time, the FW loads the saved data from the NV memory SLC area if there is a power fail event. The Host FTL driver 102 will restore the host side write buffer from the SSD DDR buffer area. Host FTL driver 102 continues the IO write from the unfinished write side buffer.

One advantage of using the PPS is that it offers faster Fsync and IO write response. For example, a host application can see a faster IO write response since the IO write can finish when the data is backup in the SSD DDR buffer. Also, the host CPU application can see faster fsync since all the IO write commands can be restored safely at the power up and reduces need to flush the write buffer at power fail or normal power down time. Another advantage of using the PPS is that it reduces a need of write amplification due to flush. For example, since the data in the host write side buffer is protected by the SSD DDR buffer with big CAP hold up power and FW save/restore procedure, there is no need to flush host side write buffer at power down. Another advantage of using the PPS is to provide efficient use of the SSD DDR buffer. For instance, in a normal operation, the backup data is written from host side to the SSD device side once so that reduces DDR write bandwidth. In yet another advantage of using the PPS is to offload the CPU processing in backup and restore. For example, backup and restore data from/to host side to/from the device side DDR buffer is done by SSD DMA function.

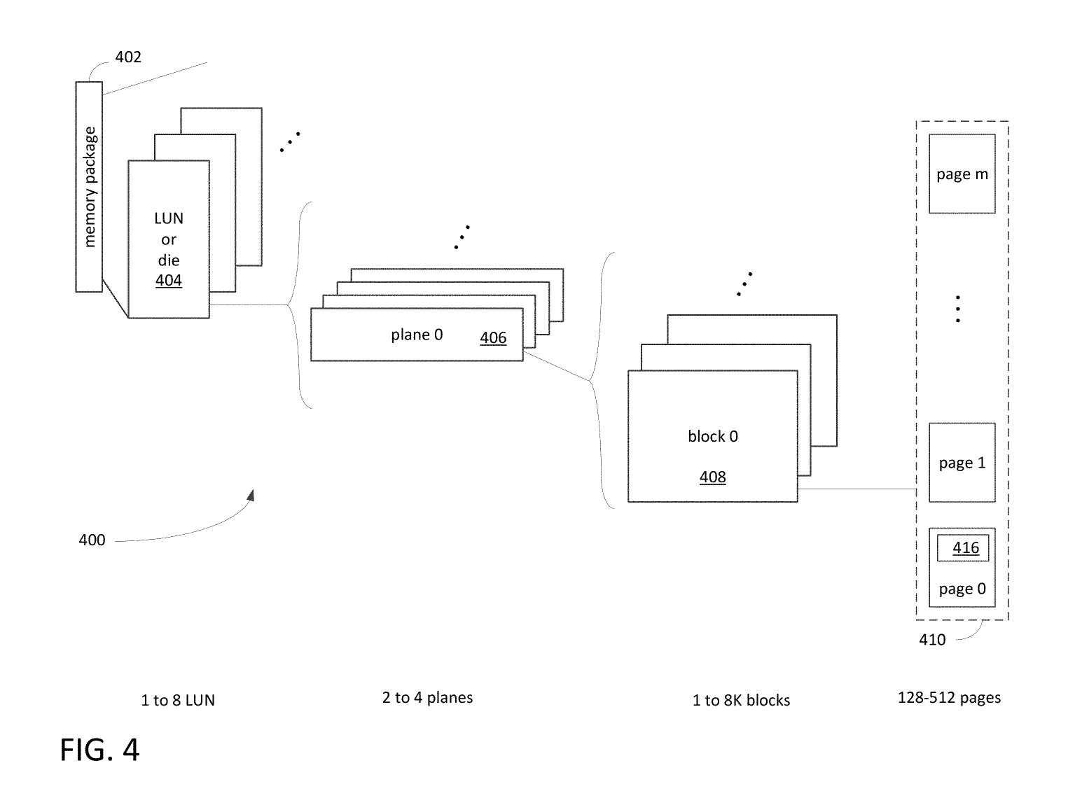

FIG. 4 is a block diagram illustrating an NVM device operating as OCSSD using the PPS in accordance with one embodiment of the present invention. Diagram 400 includes a memory package 402 which can be a memory chip containing one or more NVM dies or logic units (“LUNs”) 404. A flash memory, for example, has a hierarchy of Package-Silicon Die/LUN-Plane-Block-Flash Memory Page-Wordline configuration(s). It should be noted that the underlying concept of the exemplary embodiment(s) of the present invention would not change if one or more blocks (or devices) were added to or removed from diagram 400.

In one embodiment, an NVM memory device such as a flash memory package 402 contains one or more flash memory dies or LUNs wherein each LUN or die 404 is further organized into more NVM or flash memory planes 406. For example, die 404 may have a dual planes or quad planes. Each NVM or flash memory plane 406 can include multiple memory blocks or blocks. In one example, plane 406 can have a range of 1000 to 8000 blocks 408. Each block such as block 408 can have a range of 64 to 512 pages. For instance, a flash memory block can have 256 or 512 pages 410.

In one aspect, one flash memory page can have 8 KBytes or 16 KBytes of data plus extra redundant area for ECC parity data to be stored. One flash memory block is the minimum unit of erase. One flash memory page is the minimum unit of program. To avoid marking an entire flash memory block bad or defective which will lose anywhere from 256 to 512 flash memory pages, a page removal or decommission can be advantageous. It should be noted that 4 Megabytes (“MB”) to 16 MB of storage space can be saved to move from block decommissioning to page decommissioning.

In one embodiment, a portion of a page or a block as indicated by numeral 416 of OCSSD is designated to store data or content from an SSD local volatile memory when the power failure occurs. The SSD local volatile memory, not shown in FIG. 4, can be a RAM storage, DDR SDRAM (double data rate synchronous dynamic random-access memory), SRAM, or the like. In one aspect, the SSD local volatile memory is supported by a capacitor which will be used to maintain the data integrity in the SSD local volatile memory for a period of time so that the content of the SSD local volatile memory can be loaded into non-volatile memory as indicated by numeral 416. In one example, the non-volatile memory used in the OCSSD is SLC (single level cell) type of NVM. SLC type of NVM, for example, has a fast access speed. Depending on the applications, the size of capacitor should be set to hold the data after power failure from 1 millisecond to 25 milliseconds.

The exemplary embodiment of the present invention includes various processing steps, which will be described below. The steps of the embodiment may be embodied in machine or computer executable instructions. The instructions can be used to cause a general purpose or special purpose system, which is programmed with the instructions, to perform the steps of the exemplary embodiment of the present invention. Alternatively, the steps of the exemplary embodiment of the present invention may be performed by specific hardware components that contain hard-wired logic for performing the steps, or by any combination of programmed computer components and custom hardware components.

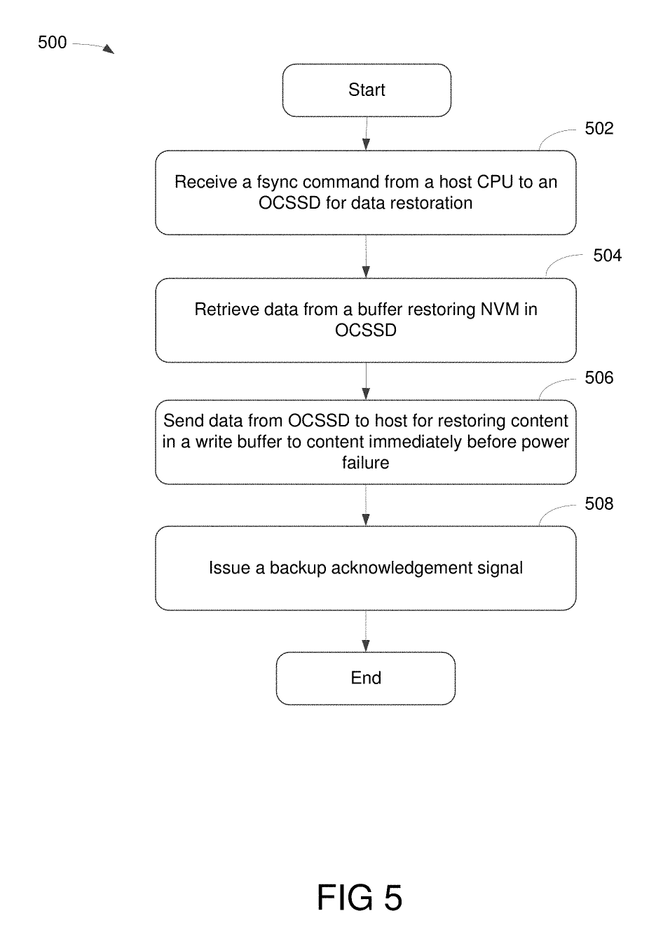

FIG. 5 is a flowchart 500 illustrating a process of data protection upon detection of an unintended power loss in an OCSSD storage environment in accordance with one embodiment of the present invention. At block 502, a process for restoring data during memory access to an OCSSD receives a fsync command from a host CPU to the OCSSD for data restoration in a write buffer in the host after a power failure.

At block 504, the process is capable of retrieving data from a buffer restoring NVM in the OCSSD. In one example, the buffer restoring NVM is a block of SSD NVM dedicated for storing the content from the write buffer in the host.

At block 506, the data is sent from the OCSSD to the host for restoring the content in the write buffer in the host to content immediately before the power failure so that memory access or IO (input/output) operation can continue. For example, the data is loaded from the SSD local memory to the write buffer in the host. Note that the data can also be loaded from the buffer restoring NVM to the write buffer in the host depending on the applications. The IO operation immediately after the power failure is subsequently resumed in response to the restored data in the write buffer.

At block 508, a backup acknowledgement signal is issued from the OCSSD to the host in response to the fsync command. In one embodiment, a copy of substantially the same content of the write buffer of the host is maintained in an SSD local memory in the OCSSD. Upon detecting the power failure, the data in the SSD local memory is maintained for a predefined period time by a capacitor for preserving the data integrity. In one example, upon detecting a power failure, a capacitor is activated to maintain content of the SSD local memory. Note that the data in the SSD local memory is be maintained by the capacitor for at least three(s) milliseconds (“ms”) which is sufficient for storing the content in the SSD local memory in an NVM. In one aspect, the capacitor is set with sufficient capacitance to maintain the data in the SSD local memory for a range between 3 ms and 25 ms after loss of power. In one embodiment, the data in the SSD local memory is transferred to a predefined NVM block for saving the data persistently while the data in the SSD local memory is maintained by the capacitor. For example, the content of the SSD local memory is loaded into an OCSSD single level cell block. In one embodiment, after detecting restoration of power, the data is restored from the predefined NVM block to the SSD local memory. In one embodiment, the process of PPS is capable of transferring the data in the SSD local memory to the buffer restoring NVM for saving the data while the data in the SSD local memory is maintained by the capacitor. Note that the data is loaded from the write buffer to a local random-access memory (“RAM”) in the OCSSD via a Peripheral Component Interconnect Express (“PCIe”) bus.

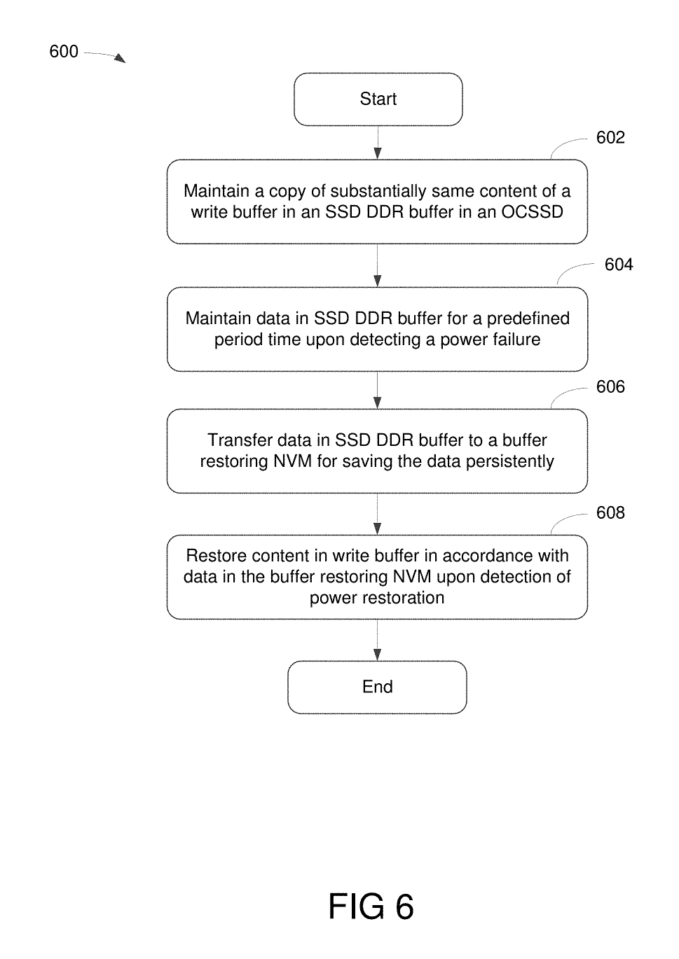

FIG. 6 is a flowchart 600 illustrating a process of data protection upon detection of an unintended power loss in an OCSSD storage environment in accordance with one embodiment of the present invention. At block 602, the process of restoring data in a buffer in a host during an unintended power failure is able to maintain a copy of substantially same content of a write buffer of the host in an SSD DDR buffer in an OCSSD.

At block 604, the data in the SSD DDR buffer is maintained for a predefined period time by a capacitor for preserving the data integrity upon detecting a power failure.

At block 606, the data in the SSD DDR buffer is transferred to a buffer restoring NVM for saving the data persistently while the data in the SSD local memory is maintained by the capacitor.

At block 608, the content in the write buffer is restored in accordance with the data in the buffer restoring NVM upon detection of power restoration. In one embodiment, after detecting restoration of power, the process is capable of restoring the data from the buffer restoring NVM to the SSD DDR buffer. Upon receiving a command from a host CPU for accessing one or more NVM pages, the data is loaded from the write buffer in a host system to the SSD DDR buffer via a bus connecting the host system and the OCSSD. A backup acknowledge signal is sent from the OCSSD to the host system when the data in the buffer is coped to the SSD DDR buffer. The process is capable of issuing an input and output (“TO”) commend acknowledge signal by the host system in response to the backup acknowledge signal.

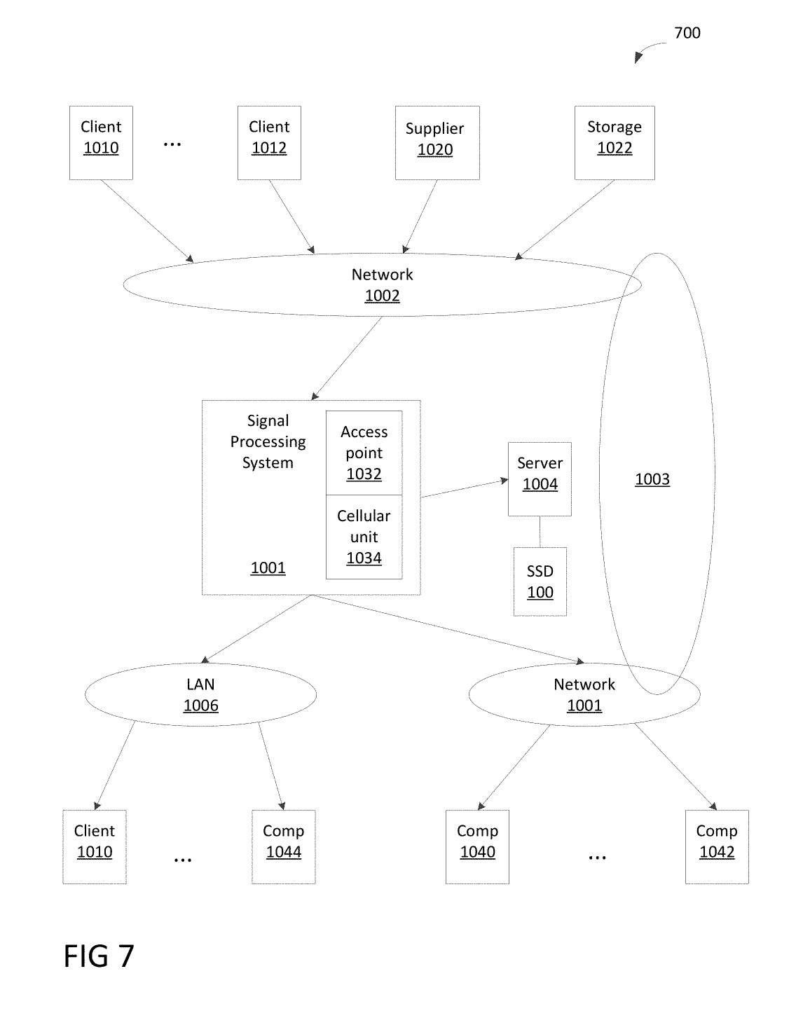

FIG. 7 is a diagram illustrating a computer network capable of providing data storage using power failure protection in the OCSSD in accordance with one embodiment of the present invention. In this network environment, a system 700 is coupled to a wide-area network 1002, LAN 1006, Network 1001, and server 1004. Wide-area network 1002 includes the Internet, or other proprietary networks including America On-Line™, SBC™, Microsoft Network™, and Prodigy™. Wide-area network 1002 may further include network backbones, long-haul telephone lines, Internet service providers, various levels of network routers, and other means for routing data between computers.

Server 1004 is coupled to wide-area network 1002 and is, in one aspect, used to route data to clients 1010-1012 through a local-area network (“LAN”) 1006. Server 1004 is coupled to SSD 100 wherein the storage controller is able to decommission or logically remove defective page(s) from a block to enhance overall memory efficiency.

The LAN connection allows client systems 1010-1012 to communicate with each other through LAN 1006. Using conventional network protocols, USB portable system 1030 may communicate through wide-area network 1002 to client computer systems 1010-1012, supplier system 1020 and storage device 1022. For example, client system 1010 is connected directly to wide-area network 1002 through direct or dial-up telephone or other network transmission lines. Alternatively, clients 1010-1012 may be connected through wide-area network 1002 using a modem pool.

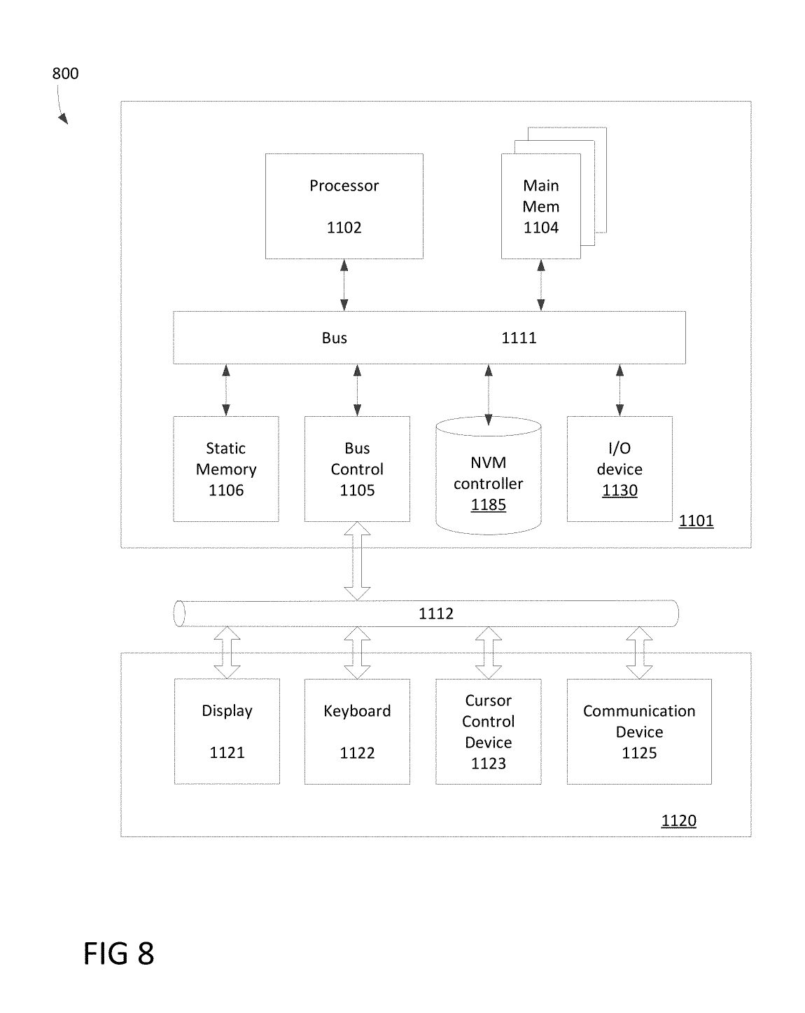

Having briefly described one embodiment of the computer network in which the embodiment(s) of the present invention operates, FIG. 8 illustrates an example of a computer system, which can be a host, memory controller, server, a router, a switch, a node, a hub, a wireless device, or a computer system.

FIG. 8 is a block diagram illustrating a digital processing system 800 capable of operating power failure protected OCSSD in accordance with one embodiment of the present invention. Computer system or a signal separation system 800 includes a processing unit 1101, an interface bus 1112, and an input/output (“IO”) unit 1120. Processing unit 1101 includes a processor 1102, a main memory 1104, a system bus 1111, a static memory device 1106, a bus control unit 1105, an I/O element 1130, and an NVM controller 1185. It should be noted that the underlying concept of the exemplary embodiment(s) of the present invention would not change if one or more blocks (circuit or elements) were added to or removed from FIG. 8.

Bus 1111 is used to transmit information between various components and processor 1102 for data processing. Processor 1102 may be any of a wide variety of general-purpose processors, embedded processors, or microprocessors such as ARM® embedded processors, Intel® Core™ Duo, Core™ Quad, Xeon®, Pentium™ microprocessor, Motorola™ 68040, AMD® family processors, or Power PC™ microprocessor.

Main memory 1104, which may include multiple levels of cache memories, stores frequently used data and instructions. Main memory 1104 may be RAM (random access memory), MRAM (magnetic RAM), or flash memory. Static memory 1106 may be a ROM (read-only memory), which is coupled to bus 1111, for storing static information and/or instructions. Bus control unit 1105 is coupled to buses 1111-1112 and controls which component, such as main memory 1104 or processor 1102, can use the bus. Bus control unit 1105 manages the communications between bus 1111 and bus 1112. Mass storage memory or SSD, which may be a magnetic disk, an optical disk, hard disk drive, floppy disk, CD-ROM, and/or flash memories are used for storing large amounts of data.

I/O unit 1120, in one embodiment, includes a display 1121, keyboard 1122, cursor control device 1123, and communication device 1125. Display device 1121 may be a liquid crystal device, cathode ray tube (“CRT”), touch-screen display, or other suitable display device. Display 1121 projects or displays images of a graphical planning board. Keyboard 1122 may be a conventional alphanumeric input device for communicating information between computer system 1100 and computer operator(s). Another type of user input device is cursor control device 1123, such as a conventional mouse, touch mouse, trackball, or other type of cursor for communicating information between system 1100 and user(s).

Communication device 1125 is coupled to bus 1111 for accessing information from remote computers or servers, such as server or other computers, through wide-area network. Communication device 1125 may include a modem or a network interface device, or other similar devices that facilitate communication between computer 1100 and the network. Computer system 1100 may be coupled to a number of servers 104 via a network infrastructure such as the infrastructure illustrated in FIG. 7.

While particular embodiments of the present invention have been shown and described, it will be obvious to those of ordinary skills in the art that based upon the teachings herein, changes and modifications may be made without departing from this exemplary embodiment(s) of the present invention and its broader aspects. Therefore, the appended claims are intended to encompass within their scope all such changes and modifications as are within the true spirit and scope of this exemplary embodiment(s) of the present invention.

What is claimed is:

1. A method for restoring data during memory access to an open-channel solid state drive (“OCSSD”), comprising:
receiving a file synchronization (“fsync”) command from a host central processing unit (“CPU”) to an OCSSD for data restoration in a write buffer in a host after a power failure;
retrieving data from a buffer restoring nonvolatile memory (“NVM”) in the OCSSD;
sending the data from the OCSSD to the host for restoring content in a write buffer in the host to content immediately before the power failure so that memory access can continue; and
issuing a backup acknowledgement signal from the OCSSD to the host in response to the fsync command.

2. The method of claim 1, further comprising maintaining a copy of substantially same content of a write buffer of the host in an SSD local memory in the OCSSD.

3. The method of claim 2, further comprising:
detecting the power failure; and
maintaining the data in the SSD local memory for a predefined period time by a capacitor for preserving the data integrity.

4. The method of claim 3, further comprising transferring the data in the SSD local memory to a predefined NVM block for saving the data persistently while the data in the SSD local memory is maintained by the capacitor.

5. The method of claim 3, further comprising transferring the data in the SSD local memory to the buffer restoring NVM for saving the data while the data in the SSD local memory is maintained by the capacitor.

6. The method of claim 4, further comprising:
detecting restoration of power; and
restoring the data from the predefined NVM block to the SSD local memory.

7. The method of claim 1, wherein sending the data from the OCSSD to the host further includes loading the data from the SSD local memory to the write buffer in the host.

8. The method of claim 1, wherein sending the data from the OCSSD to the host further includes loading the data from the buffer restoring NVM to the write buffer in the host.

9. The method of claim 7, further comprising resuming IO operation immediately after the power failure in response to the data in the write buffer.

10. The method of claim 1, further comprising loading data from the write buffer to a local random-access memory (“RAM”) in the OCSSD via a Peripheral Component Interconnect Express (“PCIe”) bus.

11. The method of claim 3, wherein detecting a power failure includes activating a capacitor to maintain content of the SSD local memory.

12. The method of claim 11 wherein activating a capacitor includes maintaining the data in the SSD local memory for at least three(s) milliseconds (“ms”).

13. The method of claim 11, wherein activating a capacitor includes setting a capacitor with sufficient capacitance to maintain the data in the SSD local memory for a range between 3 milliseconds (“ms”) and 25 ms after loss of power.

14. The method of claim 4, wherein transferring the data in the SSD local memory to a predefined NVM block includes loading content of the SSD local memory to an OCSSD single level cell block.

15. A method of restoring data in a buffer in a host during an unintended power failure comprising,
maintaining a copy of substantially same content of a write buffer of the host in a solid-state drive (“SSD”) double data rate (“DDR”) buffer in an open-channel SSD (“OCSSD”);
maintaining the data in the SSD DDR buffer for a predefined period time by a capacitor for preserving the data integrity upon detecting a power failure;
transferring the data in the SSD DDR buffer to a buffer restoring NVM for saving the data persistently while the data in the SSD local memory is maintained by the capacitor; and
restoring content in the write buffer in accordance with the data in the buffer restoring NVM upon detection of power restoration.

16. The method of claim 15, further comprising detecting restoration of power; and restoring the data from the buffer restoring NVM to the SSD DDR buffer.

17. The method of claim 15, comprising:
receiving a command from a host central processing unit (“CPU”) for accessing one or more NVM pages; and
loading data from the write buffer in a host system to the SSD DDR buffer via a bus connecting the host system and the OCSSD.

18. The method of claim 17, comprising:
sending a backup acknowledge signal from the OCSSD to the host system when the data in the buffer is coped to the SSD DDR buffer; and
issuing an input and output (“IO”) commend acknowledge signal by the host system in response to the backup acknowledge signal.

19. A power protection system configured to protect data loss during a power failure for an open-channel solid-state drive (“OCSSD”), comprising:
a host driver situated in a host system and configured to have a write buffer able to store information during a write operation to an OCSSD;
an SSD driver situated in an SSD and coupled to the host driver via an external bus, wherein the SSD driver includes:
an SSD double data rate (“DDR”) buffer configured to store a copy of content similar to content in the write buffer;
an SSD nonvolatile memory (“NVM”) coupled to the SSD DDR buffer and configured to preserve the data stored in the SSD DDR buffer when a power failure is detected; and
a power supply coupled to the SSD DDR buffer for providing power to the SSD DDR buffer when the power is lost.

20. The system of claim 19, wherein the power supply is a capacitor.
